(19) United States
(12) Patent Application Publication
(10) Pub. No.: US 2006/0001486 A1
(43) Pub. Date: Jan. 5, 2006

(54) Bias circuit for high frequency amplifiers

(76) Inventor: Kevin W. Glass, Scottsdale, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/214,670

(22) Filed: Aug. 29, 2005

Related U.S. Application Data
(62) Division of application No. 10/739,382, filed on Dec. 17, 2003.

(51) Int. Cl. H03G 3/20

(52) U.S. Cl. 330/133

(57) ABSTRACT

A method and apparatus to bias each of a plurality of stages of a limiting amplifier are described.

### BACKGROUND

A high speed optical communication system may communicate information using optical signals. Optical systems may use a limiting amplifier to amplify a received signal to a gain level sufficient for further processing by the receiver. The limiting amplifier may comprise multiple stages, with each stage being biased to produce the proper gain signals for subsequent amplifier stages. If the amplifier does not produce the proper signal levels, receiver decision threshold processing may be compromised causing communication errors. Consequently, there may be a need for improvements in biasing techniques for a device or system.

### BRIEF DESCRIPTION OF THE DRAWINGS

The subject matter regarded as embodiments is particularly pointed out and distinctly claimed in the concluding portion of the specification. The embodiments, however, both as to organization and method of operation, together with objects, features, and advantages thereof, may best be understood by reference to the following detailed description when read with the accompanying drawings in which:

FIG. 1 illustrates a block diagram of a system suitable for practicing one embodiment;

FIG. 2 illustrates a block diagram of a transceiver suitable for use in practicing one embodiment;

FIG. 3 illustrates a schematic diagram of a limiting amplifier of a system in accordance with one embodiment;

FIG. 4 is a schematic diagram of a bias circuit for a limiting amplifier in accordance with one embodiment; and

FIG. 5 is a schematic diagram of one differential stage of an amplifier in accordance with one embodiment.

### DETAILED DESCRIPTION

The embodiments relate to a high frequency amplifier bias circuit, a high frequency amplifier which uses the bias circuit, and a communication device which uses the high frequency amplifier. More particularly, the embodiment relates to a bias circuit for a multiple stage high frequency cascode amplifier for use in high speed communication systems.

In high speed optical communication systems, information signals propagate over various distances along a transmission medium, such as optical fiber. These signals are amplified during propagation by optical amplifiers disposed along the transmission medium and are incident on an optical receiver. The power levels associated with these transmitted signals vary significantly due to a number of effects such as span lengths, fiber type, splice losses, and so forth. These variations in signal power effect whether or not a particular signal is recognized by the receiver.

An optical receiver, usually configured as a transceiver to allow both transmission and reception functionality within a single line card, includes a photo-detector that converts the incident optical signals into an electrical current proportional to the power level of the received optical signals. A transimpedance amplifier converts the small signal current to a small signal input voltage. A limiting amplifier receives the input voltage signal and amplifies it to a gain level sufficient for further processing by the receiver. Because the input signal from the transimpedance amplifier is small, the gain level provided by the amplifier may be significant. This gain level is usually provided in multiple stages because high gain produced by a single stage amplifier is too unstable for high bandwidth communication receivers.

Each stage of the limiting amplifier must be biased correctly in order to produce the expected gain levels. Existing limiting amplifiers, such as cascode transistor amplifiers, require multiple bias circuits corresponding to the number of amplifier stages in order to bias the amplifier correctly to produce expected gain levels. In addition, amplifiers that employ cascode transistors must have a low impedance to AC ground and the biasing of these amplifiers must keep the cascode transistors biased in the forward active region regardless of transistor, temperature, power supply and resistor manufacturing variations. Through the use of multiple bias circuits, bias voltage coupling due to large DC bias currents is avoided. However, a drawback associated with multiple bias circuits is unwanted power consumption, as well as additional circuit complexity.

Properly biasing each stage of a multiple stage amplifier requires that each stage produce the proper gain signals which are used as inputs to subsequent amplifier stages. If the amplifier does not produce the proper signal levels, receiver decision threshold processing may be compromised causing communication errors. Therefore, proper biasing is important for amplifier operation, receiver functionality and communication system integrity. Consequently, there may be a need for a single biasing circuit configured to bias each stage of a multiple stage amplifier thereby reducing overall power consumption and circuit complexity.

To solve these and other problems, one embodiment may comprise a circuit to bias each of a plurality of stages of a high frequency differential amplifier. The bias circuit comprises a control input terminal that receives a control signal. The outputs of the bias circuit are connected to corresponding inputs of each stage of a multiple stage differential amplifier. The bias circuit includes a reference emitter-follower stage, a current bias stage and a cascode bias stage. The emitter-follower stage includes an emitter follower transistor, having a low AC impedance, that supplies a bias voltage control signal to a first output terminal of the bias circuit. This output control signal maintains the cascode transistors of each stage of the amplifier circuit in their forward active region. The current bias stage includes a transistor configured to output a current source bias signal to each stage of the multiple stage differential amplifier. The cascode stage is disposed between the emitter follower and current source bias stages. The cascode stage includes at least one transistor that regulates the voltage signal supplied to the current bias stage.

For example, one embodiment of an amplifier bias circuit provides a bias voltage to each stage of a plurality of cascode amplifier stages. In this manner, each stage of the amplifier receives a consistent bias voltage signal. The bias for the cascode transistors has a low impedance to AC ground while keeping the cascode transistors biased in the forward active region regardless of resistor, transistor, temperature, and power supply variations within the amplifier. The bias circuit described herein may accomplish these results while maintaining relatively low circuit complexity.

It is worthy to note that any reference in the specification to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

Numerous specific details may be set forth herein to provide a thorough understanding of the embodiments. It will be understood by those skilled in the art, however, that the embodiments may be practiced without these specific details. In other instances, well-known methods, procedures, components and circuits have not been described in detail so as not to obscure the embodiments. It can be appreciated that the specific structural and functional details disclosed herein may be representative and do not necessarily limit the scope of the embodiment.

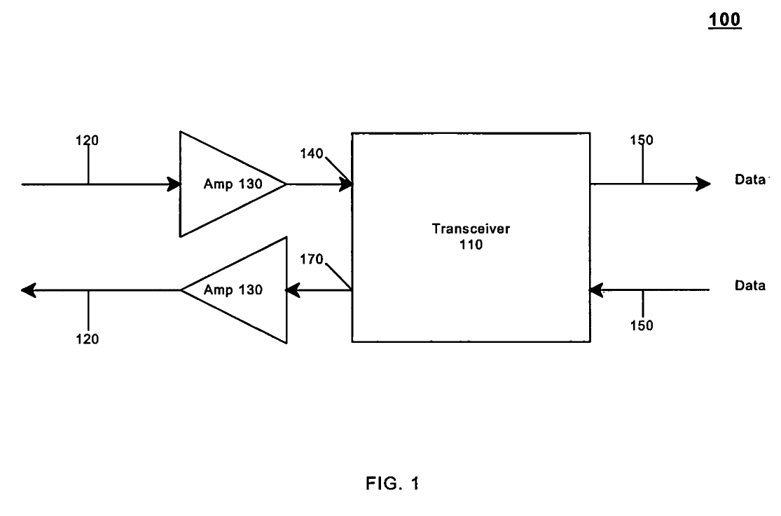

Referring now in detail to the drawings wherein like parts are designated by like reference numerals throughout, there is illustrated in FIG. 1 a system suitable for practicing one embodiment. FIG. 1 is a simplified block diagram of a communication system 100 comprising a transceiver module 110, transmission medium 120, configured to allow the propagation of a plurality of information signals, and amplifiers 130. The expression “information signals,” as used herein, refers to an optical or electrical signal which has been coded with information. System 100 is typically configured with transceivers at both ends of transmission medium 120 to accommodate bidirectional communication. For ease of explanation, transceiver module 10 is shown with receive and transmit functionality. Additional amplifiers 130 may also be disposed along transmission medium 120 depending on the desired transmission distances and associated span losses in order to provide an information signal having a power level sufficient for detection and processing by transceiver 110.

In one embodiment, transceiver module 110 is configured to receive information signals from transmission medium 120 via input 140 and output its electrical data equivalent at output 150. Transceiver module 110 is also configured to receive data from input 160 and output its corresponding optical equivalent via output 170 for propagation along transmission medium 120. Typically, optical signals incident on transceiver 110 have amplitude variations that fall outside the dynamic range of a conventional amplifier, thus requiring additional signal processing as described below.

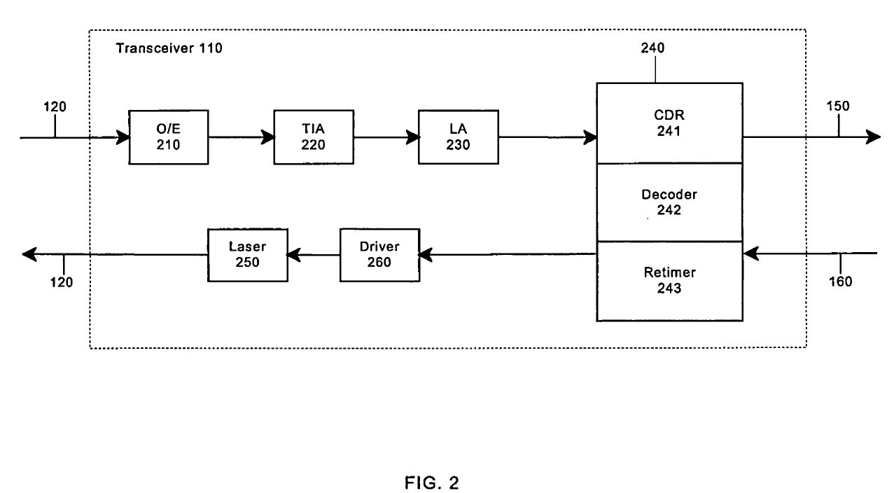

FIG. 2 illustrates a block diagram of transceiver 110 which may include an optical to electrical (O/E) converter module 210, transimpedence amplifier (TIA) 220, limiting amplifier 230, module 240 which includes a clock and data recovery circuit (CDR) 241 and decoder 242 for the receive side and laser 250, laser driver 260 and re-timer circuit or encoder 243 for the transmit side. Re-timer circuit 243 receives information signals in electrical form and supplies these signals to laser driver 260 which provides current variations proportional to the received information signals. Semiconductor laser 250 generates optical signals proportional to the received current levels for transmission over medium 120.

The receive side of transceiver 110 receives optical signals propagating along transmission medium 120 incident on O/E module 210 where optical energy is converted to small signal electrical current proportional to the received optical signals. A typical O/E module may include a semiconductor photodiode or photodetector configured to detect an individual or range of optical wavelengths. The electrical signals generated by the photodetector may be relatively weak and require conversion to a voltage equivalent as well as squaring-off of digital pulses, regenerating clock signals, and noise filtering induced by transmission and dark noise generated by the photodetector. Depending on the distances under which the optical signals travel along transmission medium 120, a preamplifier may also be disposed at or near O/E module 210 to increase the optical signal power incident on photodetector 210. For example, a preamplifier may be used to provide 1 mW of optical signal power to photodetector 210. A preamplifier is typically used in optical communication systems where signal attenuation from span losses and/or fiber nonlinearities is present.

As stated above, the small signal current generated by photodetector 210 must be converted into a corresponding voltage for further processing. This conversion is accomplished by TIA 220 which is functionally equivalent to a resistor and is typically characterized by high transimpedance on the front end and low impedance on the back end. TIA 220 provides high transimpedance with low noise amplification, but must also provide a large bandwidth for the received signals. TIA 220 may be a two stage, common-source, common-drain or a single stage, common-gate amplifier. Because the current received by TIA 220 from O/E module 210 is small, TIA 220 likewise outputs a corresponding small voltage signal. Limiting amplifier 230 functions to increase the voltage gain of the signals received from TIA 220 so that these signals may be processed by clock and data recovery (CDR) module 240. Once a clock is reestablished and the received data recovered, the signals may be forwarded to a decoding module, not shown, for error correction processing. The error correction processing may comprise, for example, Forward Error Correcting (FEC) decoding.

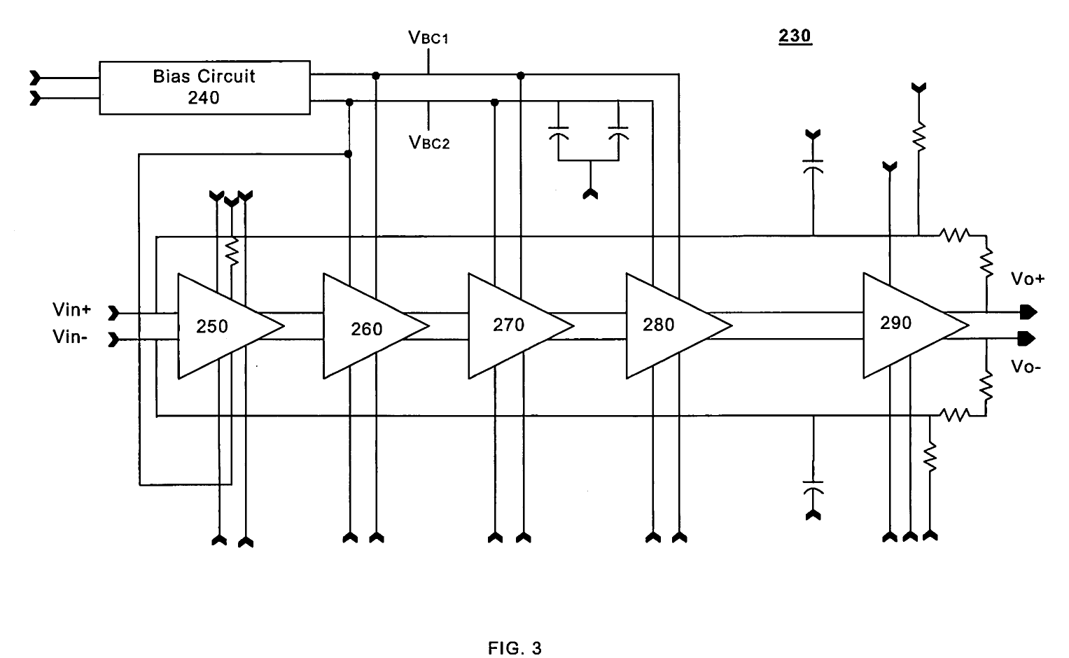

FIG. 3 illustrates a schematic diagram of a 4 stage limiting amplifier 230 having inputs 225 coupled to TIA 220. Amplifier 230 includes stages 250, 260, 270, 280 and output stage 290. Typically, the voltage levels supplied by the outputs of TIA 220 are insufficient to drive CDR 241. Therefore, limiting amplifier 230 is utilized to increase these voltage levels and provide a sufficiently high voltage gain for further signal processing. Because limiting amplifier provides such high gain, multiple stages must be used in order to avoid producing too much gain in any one stage resulting in amplifier instability. Limiting amplifier 230 has a threshold adjustment that functions like the initial level of a decision circuit or threshold circuit that detects whether the received signals are 1's or 0's, where a voltage above a certain threshold is considered a 1 and a voltage below a certain threshold is considered a 0. Because the transmitted information signals are high GHz frequencies, sharp clipping is not achieved. Rather, limiting amplifiers generally are small signal high gain amplifiers where high gain is achieved at the threshold level resulting in a softer clip.

Limiting amplifier 230 has two input voltage terminals Vin+ and Vin− and two outputs Vo+ and Vo−. Limiting amplifier 230 is may comprise a high frequency cascode amplifier having a common-emitter/common-base configuration. Limiting amplifier 230 may have a high output resistance useful in achieving large voltage gain while providing a highly stable configuration suitable for high frequency optical transceivers. High frequency cascode amplifiers provide increased bandwidth with improved reverse isolation desirable in high speed optical communication systems. Because amplifier 230 is a cascode amplifier, the cascode transistors must be biased properly in the forward active region despite resistor, transistor, power supply and temperature variations. In addition, the bias to the cascode transistors must have low impedance to ground.

As noted above, amplifier 230 acts as an initial threshold decision, and therefore, it is desirable to avoid drift of even a mV at the outputs Vₒ₊ and Vₒ₋ which may compromise signal decision processing. The biasing scheme used in amplifier 230 determines its performance. Generally, an amplifier that is poorly biased suffers in performance due to high stresses within the active devices. If the amplifier is not biased properly, input values for the next circuit stage will not be as expected and transceiver performance will be compromised.

Independent bias generator circuit 240 is coupled to the limiting amplifier 230 and is used to bias each of the first four stages 250, 260, 270 and 280 of the limiting amplifier. In particular, bias circuit 240 includes a first output V_{BC1} and a second output V_{BC2}. Output V_{BC1} is coupled to amplifier stages 250, 260, 270 and 280. Similarly, output V_{BC2} is coupled to amplifier stages 250, 260, 270 and 280. Bias circuit 240 functions to keep the cascode amplifier biased in the forward active region to avoid saturating the amplifier. In this manner, a single bias generator circuit 240 is used to bias each stage of a multi-stage limiting amplifier 230. This reduces overall power consumption as compared with multiple biasing circuits for each stage, as well as circuit complexity.

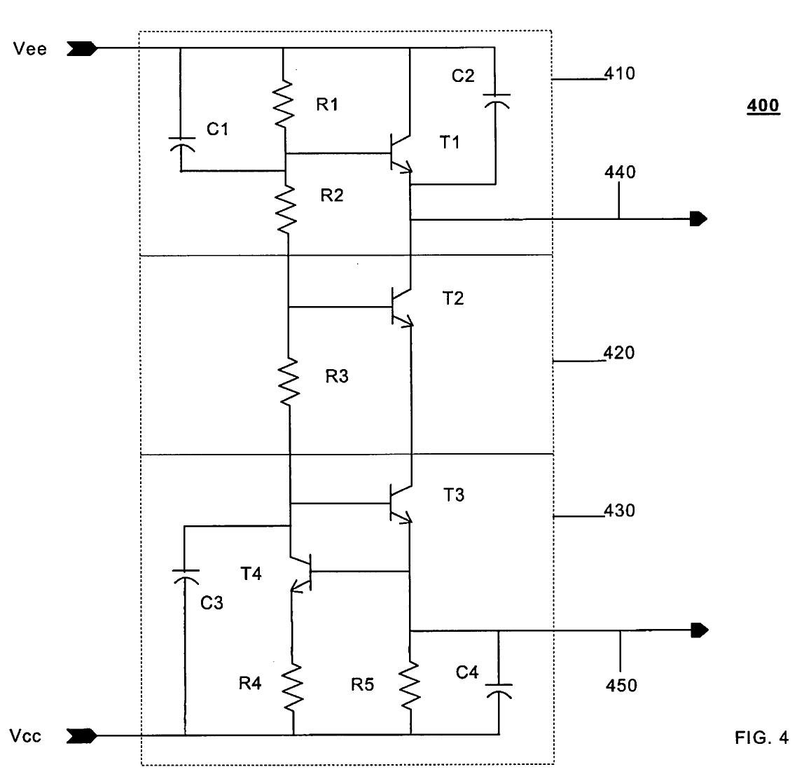

FIG. 4 illustrates bias circuit 240 in accordance with one embodiment and includes a reference emitter follower circuit 410, cascade transistor circuit 420, current source bias circuit 430 and power source terminals Vee and Vcc. Transistors T1, T2, T3 and T4 are npn transistors. Input Vee provides a voltage across capacitors C1, C2, resistors R1, R2 and collector of transistor T1 in an emitter-follower configuration where a change in base voltage Vb at T1 appears as an equal change across the load at the emitter Vbe. The emitter follower provides temperature and voltage tracking. It also provides a low impedance to AC ground. Capacitor C1 is connected between Vee and R1 and R2. Similarly, capacitor C2 is connected between Vee and the emitter of T1. Capacitors C1 and C2 function as bypass capacitors to reduce noise in the bias circuit. The ratio of resistors R1 and R2 sets the output voltage of the emitter follower T1 and capacitor C1 acts as a low pass filter to limit changes in the bias of transistor T1. The source current is set by Vbe across transistor T1 divided by R1 (Vbe/R1). Emitter follower reference circuit supplies a voltage bias to output terminal 440 which is connected to each stage 250, 260, 270 and 280 of limiting amplifier 230.

Cascode transistor circuit 420 of bias circuit 240 includes transistor T2 and resistor R3. Circuit 420 functions as a voltage regulator to the collector of transistor T3 in current source bias circuit 430. The collector of T2 is connected to the emitter of emitter follower transistor T1. Resistor R3 is connected to resistor R2 and the base of transistor T2. The voltage drop across R2 of reference emitter-follower circuit 410 plus the voltage across R3 of cascode transistor circuit R3 provides the base voltage Vb2 to transistor T2. The cascode bias is set by the current through R3 from Vcc plus the base emitter voltage Vbe of emitter follower transistor T1 of reference emitter follower circuit 410.

Current source bias circuit 430 includes transistors T3 and T4, capacitor C3 and C4 and resistors R4 and R5. Capacitor C3 is connected to the base of transistor T3, the collector of transistor T4 and Vcc. Capacitor C4 is connected to the base of transistor T4 and the emitter of transistor T3. Capacitors C3 and C4 provide noise filtering for the bias circuit. The base of transistor T3 together with the collector of T4 are commonly connected via resistor R3 and capacitor C3. The collector of transistor T4 is connected to resistor R3 and resistor R4 is connected to the emitter of transistor T4 to ground. The current through transistor T3 drops across resistor R5. This allows the Vbe bias of transistor T4 and the current to feed back through the emitter follower circuit. Output terminal 450 supplies the current source bias for each stage 250, 260, 270 and 280 of limiting amplifier 230.

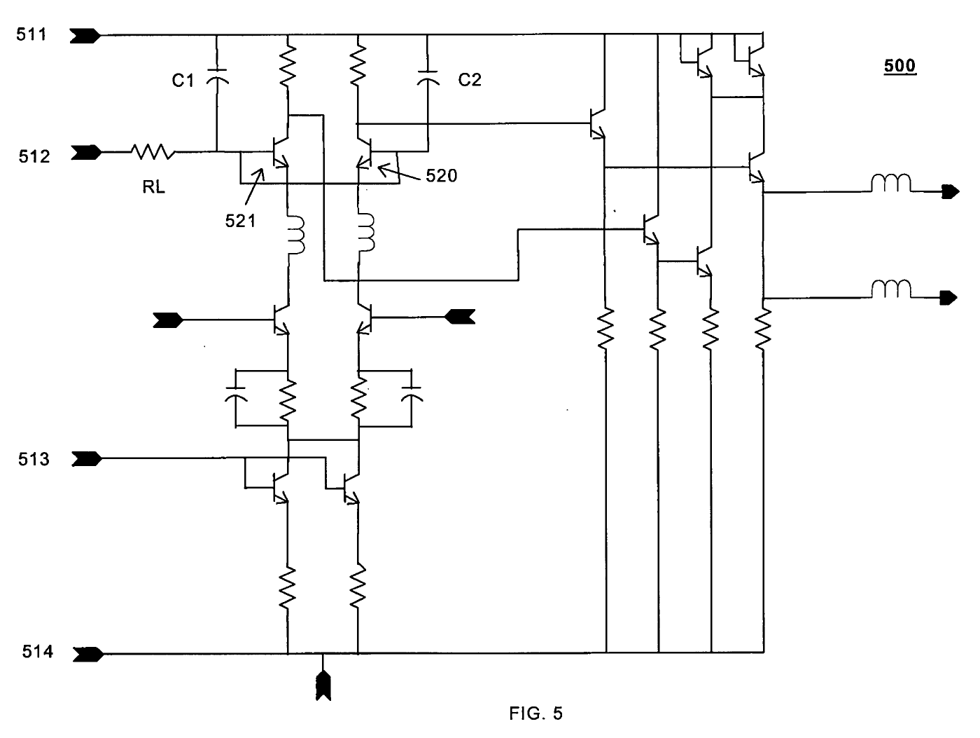

FIG. 5 illustrates a schematic of an exemplary known differential stage 250 of a multi-stage high frequency cascode amplifier 230. Although stage 250 has been selected, the following description is applicable to each of the plurality of stages of amplifier 230. As previously explained, the bias voltage from bias generator circuit 240 may supply multiple differential stages of limiting amplifier 230. Differential amplifier stage 250 includes inputs 511, 512, 513 and 514 and outputs 525 and 526. A low value resistor R_{L}, for example a 50 ohm resistor, at the bias input to each amplifier stage provides noise isolation between the respective amplifier stages. The bases of cascode transistors 520 and 521 are connected via bypass capacitors C₁ and C₂. The low value resistor R_{L} and bypass capacitors C₁ and C₂ provide a low pass filtering effect for a particular differential stage 250 of amplifier 230. In addition, this configuration also maintains a low AC impedance to ground at the respective bases of transistors 520 and 521. The bias generator cascode voltage corresponds with the source current and resistor values R_{L} of each differential stage of amplifier 230.

While certain features of the embodiments have been illustrated as described herein, many modifications, substitutions, changes and equivalents will now occur to those skilled in the art. It is, therefore, to be understood that the appended claims are intended to cover all such modifications and changes as fall within the true spirit of the embodiments.

1-9. (canceled)

10. A communication system comprising:
a transmission medium configured to allow propagation of information signals;
a receiver coupled to said transmission medium, said receiver including a plurality of interconnected amplifying stages each of said stages having at least one transistor for amplification; and
a bias control circuit having a first and second outputs connected to each of said amplifying stages, wherein said bias control circuit comprises an emitter follower transistor having a low AC impedance to supply a bias voltage control signal to each of said plurality of amplifying stages, said bias signal maintaining said amplifier stage in a forward active region and a current bias transistor connected to said emitter follower transistor for supplying a current source bias signal to each of said plurality of amplifying stages.

11. The system in accordance with claim 10 wherein said high frequency amplifier is a cascode amplifier.

12. The system in accordance with claim 10 further comprising first and second resistors connected to said emitter follower transistor.

13. The system in accordance with claim 10 further comprising first and second capacitors connected to said emitter follower transistor and configured to act as a low pass filter.

14. The system in accordance with claim 10 further comprising a low value resistor disposed between each of said plurality of amplifying stages.

15. The system in accordance with claim 10 further comprising a bypass capacitor connected to each of said at least one transistor for amplification.

16. The system in accordance with claim 14, wherein said low value resistor provides noise isolation between said plurality of amplifying stages.

17. The system in accordance with claim 15, wherein said bypass capacitor provides a localized low pass filtering effect for each of said plurality of amplifying stages.

18-20. (canceled)
